(19) United States
(12) Patent Application Publication
(10) Pub. No.: US 2025/0176172 A1
(43) Pub. Date: May 29, 2025

(54) SEMICONDUCTOR DEVICE

(71) Applicant: SAMSUNG ELECTRONICS CO., LTD., Suwon-si (KR)

(72) Inventor: Dongkyun Lim, Suwon-si (KR)

(21) Appl. No.: 18/756,601

(22) Filed: Jun. 27, 2024

(30) Foreign Application Priority Data
Nov. 27, 2023 (KR) 10-2023-0167241

(51) Int. Cl. H10B 12/00; G11C 5/06; H01L 23/528

(52) U.S. Cl. CPC H10B 12/485; G11C 5/063; H01L 23/5283; H10B 12/482; H10B 12/488

(57) ABSTRACT

An example semiconductor device includes a stack structure including a plurality of layers stacked on a substrate. Each layer includes a bit line structure including a bit line extending in a first direction parallel with the substrate, a bit line connection portion connecting the bit line structure and a wiring layer and extending in a third direction perpendicular to the substrate, a semiconductor pattern electrically connected to the bit line and extending in a second direction intersecting with the first direction, a word line structure including a word line extending in the third direction and a word line protrusion protruding in the first direction from the word line, and a capacitor electrically connected to the semiconductor pattern. The word line faces a first surface of the semiconductor pattern perpendicular to the substrate, and the word line protrusion faces a second surface of the semiconductor pattern parallel with the substrate.

### CROSS-REFERENCE TO RELATED APPLICATION

This application claims priority to and the benefit of Korean Patent Application No. 10-2023-0167241 filed in the Korean Intellectual Property Office on Nov. 27, 2023, the entire contents of which are incorporated herein by reference.

### BACKGROUND

There is a need for technologies for increasing the degrees of integration of semiconductor devices. In the case of two-dimensional semiconductor devices, the degrees of integration are mainly determined by the areas occupied by unit memory cells, and the degrees of integration in this aspect may depend on the levels of micropatterning techniques.

The micropatterning techniques require expensive equipment. Therefore, although the degrees of integration of two-dimensional semiconductor devices are increasing, it is still limited. Accordingly, three-dimensional memory devices having memory cells arranged in three dimensions are being proposed.

### SUMMARY

The present disclosure relates to semiconductor devices, including a semiconductor device with improved electrical characteristics and a higher degree of integration.

In general, according to some aspects, a semiconductor device includes a stack structure in which a plurality of layers is stacked on a substrate, and each of the plurality of layers includes a bit line structure that includes a bit line extending in a first direction parallel with the substrate, a bit line connection portion that connects the bit line structure and a wiring layer and extends in a third direction perpendicular to the substrate, a semiconductor pattern that is electrically connected to the bit line and extends in a second direction intersecting with the first direction, a word line structure that includes a word line extending in the third direction, and a word line protrusion protruding in the first direction from the word line, and a capacitor that is electrically connected to the semiconductor pattern, and the word line faces the surface of the semiconductor pattern perpendicular to the substrate, and the word line protrusion faces the surface of the semiconductor pattern parallel with the substrate.

In general, according to some aspects, a semiconductor device includes a stack structure in which a plurality of layers is stacked on a substrate, and each of the plurality of layers includes a bit line structure that includes a bit line extending in a first direction parallel with the substrate, and a bit line protrusion protruding from the bit line in a second direction intersecting with the first direction, a bit line connection portion that extends through the bit line protrusion in the third direction, a semiconductor pattern that is electrically connected to the bit line and extends in the second direction, a word line structure that includes a word line extending in the third direction perpendicular to the substrate, and a word line protrusion protruding in the first direction from the word line, and a capacitor that is electrically connected to the semiconductor pattern, and the word line faces a first surface of the semiconductor pattern, and the word line protrusion faces a second surface of the semiconductor pattern, and the second surface extends vertically from the first surface.

In general, according to some aspects, a semiconductor device includes bit line structures that each of the bit line structures includes a bit line extending in a first direction parallel with a substrate, and a bit line protrusion protruding from the bit line in a second direction intersecting with the first direction, bit line connection portions that each of the bit line connection portions extends from the bit line protrusion in a third direction perpendicular to the substrate, semiconductor patterns that each of the semiconductor patterns is connected to the bit line and extends in the second direction, a capacitor that is connected to the semiconductor pattern, and a word line structure that includes a word line which faces one side surface of the semiconductor pattern and extends in the third direction, and a word line protrusion which protrudes in the first direction from the word line and faces the upper surface of the semiconductor pattern.

In general, according to some aspects, it is possible to separately dispose wiring layers to be connected to bit lines and word lines, on and below a cell region, thereby reducing the area that is occupied by the regions where the bit lines and a wiring layer are connected to each other. Therefore, the degree of integration of a semiconductor device can be improved.

In general, according to some aspects, voltage wiring lines for supplying power to capacitors may be separately disposed on and below a cell region. In this case, it is possible to minimize the area on a plane which is occupied by wiring lines, thereby increasing the degree of freedom of wiring, and since it is possible to disconnect the wiring lines according to electric charge, it is possible to minimize unexpected charge loss due to capacitors and resistors.

In general, according to some aspects, a channel area can be increased, whereby the electrical characteristics of a semiconductor device can be improved.

### BRIEF DESCRIPTION OF THE DRAWINGS

FIG. 1 is a perspective view illustrating an example of a semiconductor device.

FIG. 2 is an enlarged perspective view of an example of a unit cell of the semiconductor device of FIG. 1.

FIG. 3 is a perspective view illustrating an example of a word line structure of the semiconductor device.

FIG. 4 is an example view illustrating the semiconductor device as viewed in the 11 direction of FIG. 1.

FIG. 5 is an example view illustrating the semiconductor device as viewed in the 2 direction of FIG. 1.

FIG. 6 is a cross-sectional view illustrating an example of a semiconductor device.

FIG. 7 is a cross-sectional view illustrating an example of core/peripheral regions of the semiconductor device.

FIGS. 8, 10, 12, 14, 17, 19, 21, 23, and 25 are perspective views illustrating an example of a method of manufacturing a semiconductor device.

FIGS. 9, 11, 13, 15, 16, 18, 20, 22, 24, and 26 are example cross-sectional views illustrating the method of manufacturing the semiconductor device.

### DETAILED DESCRIPTION

In the following detailed description, only certain implementations have been shown and described, by way of illustration. The present disclosure can be variously implemented and is not limited to the following implementations.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thicknesses of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

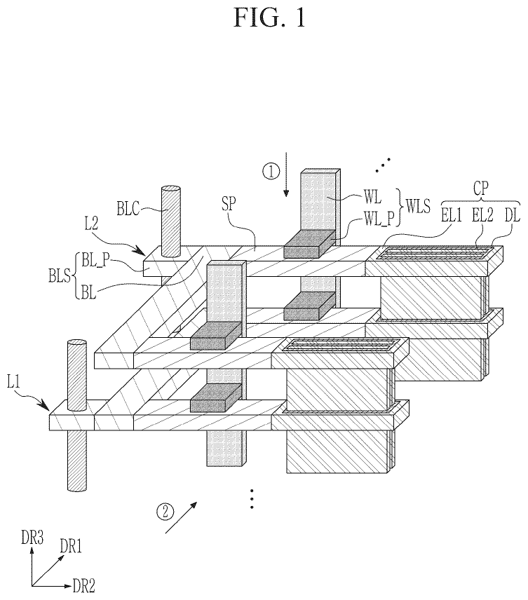

Hereinafter, the cell structures of semiconductor devices according to some implementations will be described with reference to FIGS. 1 to 5. Semiconductor devices according to some implementations may include memory cells stacked in three dimensions.

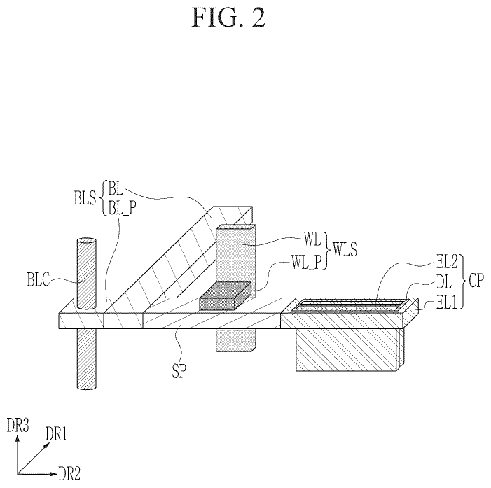

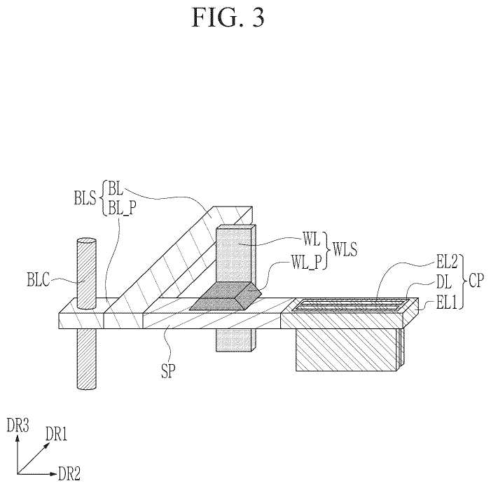

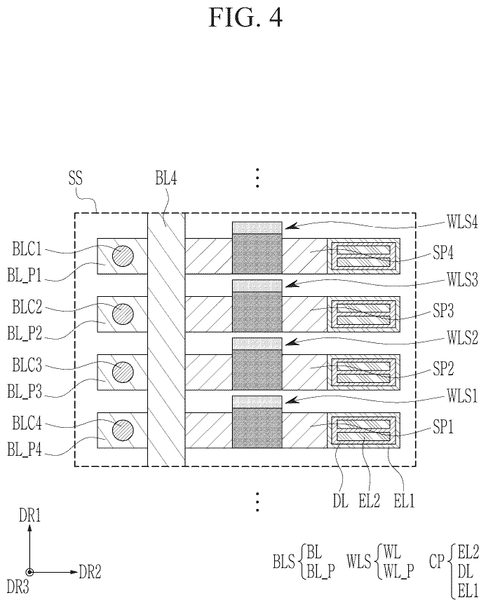

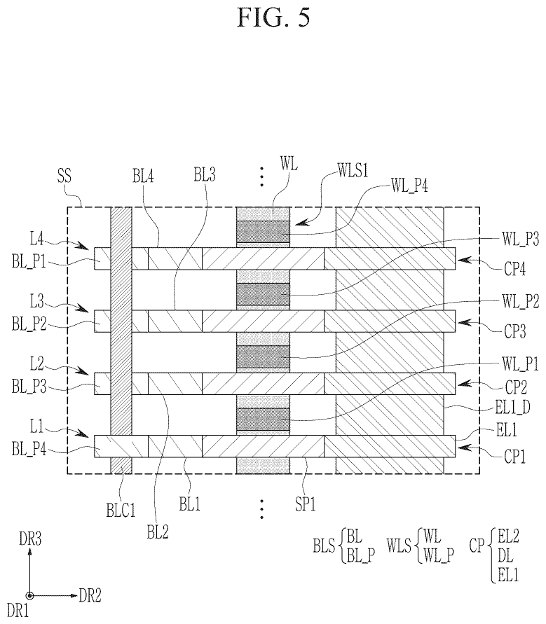

FIG. 1 is a perspective view illustrating an example of a semiconductor device. FIG. 2 is an enlarged perspective view of an example of a unit cell of the semiconductor device of FIG. 1. FIG. 3 is a perspective view illustrating an example of a word line structure of the semiconductor device. FIG. 4 is an example view illustrating the semiconductor device as viewed in the \textcircled{1} direction of FIG. 1. FIG. 5 is an example view illustrating the semiconductor device as viewed in the \textcircled{2} direction of FIG. 1. For convenience, from FIGS. 1 to 5, a substrate and insulating layers are omitted.

Referring to FIGS. 1 to 5, a semiconductor device may include a stack structure SS including a plurality of layers stacked on a substrate. The plurality of layers may be stacked in a direction perpendicular to the substrate (for example, in a third direction DR3).

FIGS. 1, 4, and 5 may show some layers of the stack structure SS except for the uppermost layer and the lowermost layer. FIGS. 2 and 3 may show one layer of some layers shown in FIG. 1.

For convenience, in FIG. 1, two layers of the stack structure SS and two cells included in each layer are shown, and in FIGS. 4 and 5, four layers of the stack structure SS and four cells included in each layer are shown; however, the stack structure SS may include more layers, and each layer may include more cells. A plurality of cells in each layer may be arranged according to a first direction DR1 and a second direction DR2. The first direction DR1 and the second direction DR2 may be parallel with the substrate and intersect each other. For example, the second direction DR2 may be orthogonal to the first direction DR1. As the plurality of layers is stacked, the plurality of cells in the individual layers may be arranged along the third direction DR3. The third direction DR3 may be a direction perpendicular to the substrate.

Further, in FIGS. 1, 4, and 5, in each layer of the stack structure SS, one bit line structure BLS is shown; however, each layer may include a plurality of bit line structures BLS which is arranged along the second direction DR2. A plurality of cells that is arranged along the first direction DR1 may be connected to the same bit line structure BLS. Even to bit line structures BLS adjacent to the bit line structures BLS shown in the drawings in the second direction DR2, a plurality of cells that is arranged along the first direction DR1 may be connected.

Furthermore, in FIG. 1, two word line structures WLS of the stack structure SS are shown, and in FIGS. 4 and 5, four word line structures WLS of the stack structure SS are shown; however, the stack structure SS may include more word line structures WLS which are arranged along the first direction DR1. Each of the plurality of word line structures WLS that is arranged along the first direction DR1 may be connected to a plurality of cells arranged along the first direction DR1. The plurality of cells that is included in the plurality of individual layers, respectively, and is arranged along the third direction DR3 may be connected to the same word line structure WLS.

In FIGS. 1, 4, and 5, one string of word line structures WLS arranged along the first direction DR1 is shown; however, a plurality of strings each including word line structures WLS arranged along the first direction DR1 may be arranged along the second direction DR2. A plurality of cells that is arranged along the second direction DR2 may be connected to a plurality of word line structures WLS that is arranged along the second direction DR2, respectively.

Referring to FIG. 1, the stack structure SS of the semiconductor device may include a first layer L1 and a second layer L2. The first layer L1 and the second layer L2 may be sequentially stacked in the third direction DR3. The first layer L1 and the second layer L2 may be spaced apart in the third direction DR3 by an insulating layer. Each of the first layer L1 and the second layer L2 may include bit line structures BLS, bit line connection portions BLC, semiconductor patterns SP, word line structures WLS, and capacitors CP.

The bit line structures BLS may include bit lines BL that extend in the first direction DR1 and bit line protrusions BL_P that protrude in the second direction DR2 from the bit lines BL. The bit line protrusions BL_P may protrude in the second direction DR2 from the surfaces of the bit lines BL facing their surfaces which are in contact with the semiconductor pattern SP to be described below. In other words, one side of each bit line BL may be connected to a semiconductor pattern SP, and the other side of the corresponding bit line BL may be connected to a bit line protrusion BL_P.

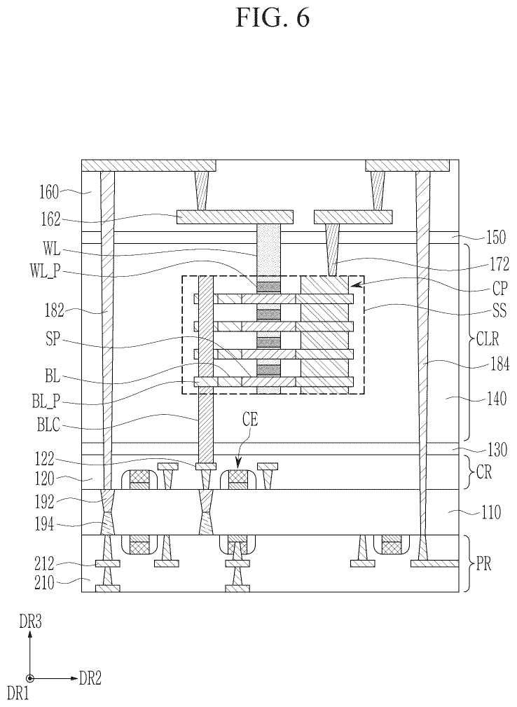

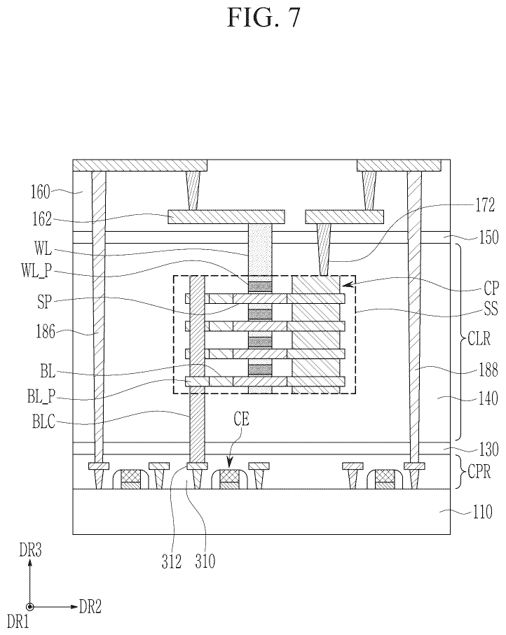

The bit line connection portions BLC may connect the bit line structures BLS and a wiring layer. The structure in which the bit line connection portions BLC connect the bit line structures BLS and the wiring layer will be described in more detail with reference to FIGS. 6 and 7.

The bit line connection portions BLC may extend in the third direction DR3 through the plurality of layers of the stack structure SS. The bit line connection portions BLC may extend in the third direction DR3 through the bit line protrusions BL_P included in any one layer of the plurality of layers. For example, the bit line connection portions BLC may extend in the third direction DR3 so as to completely penetrate through the upper surfaces and lower surfaces of the bit line protrusions BL_P; however, the bit line connection portions are not limited thereto. As another example, the bit line connection portions BLC may extend in the third direction DR3 such that one end portion of each bit line connection portion is positioned inside a bit line protrusion BL_P and the other portion thereof penetrates through only one surface of the upper surface and lower surface of the bit line protrusion BL_P.

The bit line connection portions BLC may be connected to the bit lines BL via the bit line protrusions BL_P.

The bit line structures BLS and the bit line connection portions BLC may contain conductive materials, respectively. Each conductive material may be, for example, any one of doped semiconductor materials such as doped silicon or doped germanium, conductive metal nitrides such as titanium nitride or tantalum nitride, metals such as tungsten, titanium, or tantalum, or metal-semiconductor compounds such as tungsten silicide, cobalt silicide, or titanium silicide.

The plurality of bit line structures BLS may be stacked along the third direction DR3 while being spaced apart from each other. Specifically, the plurality of bit lines BL may overlap in the third direction DR3. The plurality of bit line protrusions BL_P may not overlap in the third direction DR3. The plurality of bit line connection portions BLC may not overlap in the third direction DR3.

The semiconductor patterns SP may extend in the second direction DR2. The semiconductor patterns SP may contain, for example, silicon, germanium, silicon-germanium, or indium gallium zinc oxide (IGZO). The semiconductor patterns SP may include impurity regions, and channel regions between the impurity regions. The impurity regions may correspond to the source/drain regions of memory cell transistors.

The impurity regions may be regions in the semiconductor patterns SP doped with impurities. The impurity regions may have n-type or p-type conductivity. The impurity regions may be formed adjacent to both ends of each semiconductor pattern SP.

Each semiconductor pattern SP may have a cuboid shape having an upper surface, a lower surface, and four side surfaces. The upper surface and lower surface of each semiconductor pattern SP may be parallel with the substrate, and four side surfaces of each semiconductor pattern SP may be perpendicular to the substrate. Each semiconductor pattern SP may have a first side surface and a second side surface facing each other in the second direction DR2, and a third side surface and a fourth side surface facing each other in the first direction DR1. The third side surface may be connected to edges of the first side surface and the second side surface positioned on one side, and the fourth side surface may be connected to edges of the first side surface and the second side surface positioned on the opposite side to the one side.

The first side surfaces of the semiconductor patterns SP may be connected to the bit lines BL. The semiconductor patterns SP may be electrically connected to the bit lines BL. The second side surfaces of the semiconductor patterns SP may be connected to the capacitors CP to be described below. Specifically, the second side surfaces of the semiconductor patterns SP may be connected to first capacitor electrodes CP1 of the capacitors CP. The semiconductor patterns SP may be electrically connected to the capacitors CP.

The third side surfaces or fourth side surfaces of the semiconductor patterns SP may face the word line structures WLS to be described below. The following description will be made on the assumption that the side surfaces of the semiconductor patterns SP facing the word line structures WLS are the third side surfaces.

Each of the first layer L1 and the second layer L2 may include a plurality of semiconductor patterns SP. In each layer, the plurality of semiconductor patterns SP may be arranged along the first direction DR1 while being spaced apart from each other. The plurality of semiconductor patterns SP that is arranged along the first direction DR1 may be connected to the same bit line BL.

Although not shown in the drawings, in each layer, a plurality of bit line structures BLS may be arranged along the second direction DR2 while being spaced apart from each other. Even to a bit line BL adjacent to a bit line BL shown in each layer in the second direction DR2, a plurality of semiconductor patterns SP that is arranged along the first direction DR1 may be connected.

The plurality of semiconductor patterns SP included in the first layer L1 may overlap the plurality of semiconductor patterns SP included in the second layer L2 in the third direction DR3, respectively. In other words, a plurality of semiconductor patterns SP may be included in the first layer L1 and the second layer L2, respectively, and be arranged along the third direction DR3. A plurality of semiconductor patterns SP that is arranged along the third direction DR3 may face the same word line structure WLS.

The word line structures WLS may include word lines WL that extend in the third direction DR3 through the stack structure SS and word line protrusions WL_P that protrude in the first direction DR1 from the word lines WL. Each word line WL may face the third side surfaces of a plurality of semiconductor patterns SP that is arranged along the third direction DR3. A plurality of semiconductor patterns SP that is arranged along the third direction DR3 may be included in the plurality of layers of the stack structure SS, respectively. For example, the word lines WL may extend along the third direction so as to face the third side surfaces of the semiconductor patterns SP included in the first layer L1 and the third side surfaces of the semiconductor patterns SP included in the second layer L2.

To one word line WL, a plurality of word line protrusions WL_P may be connected. A plurality of word line protrusions WL_P connected to one word line WL may face the upper surfaces of a plurality of semiconductor patterns SP that is arranged along the third direction DR3, respectively. For example, of a plurality of word line protrusions WL_P protruding from one word line WL, any one may face the upper surface of a semiconductor pattern SP included in the first layer L1, and another one may face the upper surface of a semiconductor pattern SP included in the second layer L2.

In some implementations, it is shown that the word line protrusions WL_P face the upper surfaces of the semiconductor patterns SP; however, they are not limited thereto. As an example, the word line protrusions WL_P may face the lower surfaces of the semiconductor patterns SP. As another example, two word line protrusions WL_P may be provided so as to face the upper surface and lower surface of a semiconductor pattern SP.

The word line structures WLS may contain a conductive material. The conductive material may be, for example, any one of doped semiconductor materials, conductive metal nitrides, metals, or metal-semiconductor compounds.

Although not shown in the drawings, between the surfaces of the word line structures WLS and the semiconductor patterns SP facing each other, gate insulating layers may be positioned. For example, between the word lines WL and the third side surfaces of the semiconductor patterns SP and between the word line protrusions WL_P and the upper surfaces of the semiconductor patterns SP, gate insulating layers may be positioned.

A plurality of word line structures WLS may be arranged along the first direction DR1 while being spaced apart from each other. The plurality of word lines WL may be disposed adjacent to a plurality of semiconductor patterns SP arranged along the first direction DR1, respectively. Although not shown in the drawings, a plurality of word line structures WLS may be arranged along the second direction DR2 while being spaced apart from each other. The word line structures WLS that is arranged along the second direction DR2 may be disposed adjacent to a plurality of semiconductor patterns SP that is arranged along the second direction DR2, respectively.

The capacitors CP may be memory elements for storing data. Each capacitor CP may include a first capacitor electrode EL1 that is that has the form of a pillar surrounded by a side wall, a second capacitor electrode EL2 that passes through the first capacitor electrode EL1 in the third direction DR3, and a dielectric layer DL that is positioned between the first capacitor electrode EL1 and the second capacitor electrode EL2.

The first capacitor electrodes EL1 may be in contact with the semiconductor patterns SP. As described above, the second side surfaces of the semiconductor patterns SP may be in contact with the first capacitor electrodes EL1. The second side surfaces of the semiconductor patterns SP may be in contact with the side walls of the first capacitor electrodes EL1. Accordingly, the semiconductor patterns SP and the capacitors CP may be electrically connected to each other.

For example, the side wall of each first capacitor electrode EL1 may include portions extending in the first direction DR1 and portions extending in the second direction DR2, whereby the first capacitor electrodes EL1 may have a square pillar shape; however, the first capacitor electrodes are not limited thereto.

The first capacitor electrodes EL1 may have a hollow pillar shape. The second capacitor electrodes EL2 may extend in the third direction DR3 through the first capacitor electrodes EL1. The second capacitor electrodes EL2 may be positioned in the interior spaces of the first capacitor electrodes EL1 having a hollow pillar shape. In FIG. 1, it is shown that two separate second capacitor electrodes EL2 pass through one first capacitor electrode EL1; however, the present disclosure is not limited thereto. As another example, one second capacitor electrode EL2 may pass through one first capacitor electrode EL1, or more second capacitor electrodes may pass through one first capacitor electrode.

Each of the first capacitor electrodes EL1 and the second capacitor electrodes EL2 may contain at least one of metal materials such as titanium, tantalum, tungsten, copper, or aluminum, conductive metal nitrides such as titanium nitride or tantalum nitride, or doped semiconductor materials such as doped silicon or doped germanium.

The dielectric layers DL may be positioned between the first capacitor electrodes EL1 and the second capacitor electrodes EL2 so as to insulate the first capacitor electrodes EL1 and the second capacitor electrodes EL2 from each other. The dielectric layers DL may be formed so as to conform to the profiles of the first capacitor electrodes EL1.

The dielectric layers DL may contain a high-dielectric constant material. The high-dielectric constant material may contain, for example, hafnium oxide, hafnium silicon oxide, zirconium oxide, zirconium silicon oxide, aluminum oxide, lanthanum oxide, tantalum oxide, titanium oxide, barium strontium titanium oxide, strontium titanium oxide, lithium oxide, lead scandium tantalum oxide, lead zinc niobate, or a combination thereof.

In each layer, a plurality of capacitors CP may be arranged along the first direction DR1. In each layer, the plurality of capacitors CP arranged along the first direction DR1 may be electrically connected to the semiconductor patterns SP arranged along the first direction DR1, respectively.

A plurality of capacitors CP may be arranged along the third direction DR3. The plurality of capacitors CP that is arranged along the third direction DR3 may share one second capacitor electrode EL2. Each second capacitor electrode EL2 may extend through the first capacitor electrodes EL1 of the plurality of layers. Capacitors that are included in the plurality of layers, respectively, and are arranged along the third direction DR3 may share a second capacitor electrode EL2. For example, a second capacitor electrode EL2 may extend through a first capacitor electrode EL1 of the first layer L1 and a first capacitor electrode EL1 of the second layer L2. Capacitors that are included in the first layer L1 and the second layer L2, respectively, and are arranged along the third direction DR3 may share a second capacitor electrode EL2.

Referring to FIG. 2, the unit cells of the semiconductor device of FIG. 1 may include the semiconductor patterns SP, the bit line structures BLS, the bit line connection portions BLC, the capacitors CP, and the word line structures WLS, positioned on the substrate.

The semiconductor patterns SP may extend in the second direction DR2. Each semiconductor pattern SP may have a first side surface and a second side surface facing each other in the second direction DR2. The first side surfaces of the semiconductor patterns SP may be in contact with the bit line structures BLS. The second side surfaces of the semiconductor patterns SP may be in contact with the capacitors CP.

The bit line structures BLS may include the bit lines BL that extend in the first direction DR1 and the bit line protrusions BL_P that protrude in the second direction DR2 from the bit lines BL. The first direction and the second direction may be parallel with the substrate, and be orthogonal to each other.

The bit lines BL may be in contact with the first side surfaces of the semiconductor patterns SP. On one side of each bit line BL, semiconductor patterns SP are positioned, and on the opposite side, bit line protrusions BL_P may be positioned. In FIG. 2, it is shown that a semiconductor pattern SP and a bit line protrusion BL_P are arranged in a straight line in the second direction DR2; however, the present disclosure is not limited thereto. For example, the bit line protrusions BL_P may be positioned so as to be misaligned with the semiconductor patterns SP in the second direction DR2.

The bit line structures BLS may include the bit line connection portions BLC that extend from the bit line protrusions BL_P in the third direction DR3 perpendicular to the substrate. The bit line connection portions BLC may extend in the third direction DR3 through the bit line protrusions BL_P. In FIG. 2, it is shown that a bit line connection portion BLC passes through a bit line protrusion BL_P; however, the bit line connection portions are not limited thereto. For example, the upper surfaces of the bit line connection portions BLC may be positioned at a level equal to or lower than the level of the upper surfaces of the bit line protrusions BL_P, or the lower surfaces of the bit line connection portions BLC may be positioned at a level equal to or higher than the level of the lower surfaces of the bit line protrusions BL_P.

The word line structures WLS may include the word lines WL that extend in the third direction DR3 perpendicular to the substrate and the word line protrusions WL_P that protrude in the first direction DR1 from the word lines WL.

The word lines WL may face the third side surfaces of the semiconductor patterns SP connecting the edges of the first side surfaces and the second side surfaces positioned on one side. The word line protrusions WL_P may face the upper surfaces of the semiconductor patterns SP.

The regions of the semiconductor patterns SP facing the word line structures WLS may serve as channels. For example, the third side surfaces of the semiconductor patterns SP facing the word lines WL and the upper surfaces of the semiconductor patterns SP facing the word line protrusions WL_P may be channel regions.

Although not shown in the drawings, between the word line structures WLS and the semiconductor patterns SP, the gate insulating layers may be positioned. For example, between the word lines WL and the third side surfaces of the semiconductor patterns SP and between the word line protrusions WL_P and the upper surfaces of the semiconductor patterns SP, gate insulating layers may be positioned.

The capacitors CP may include the first capacitor electrodes EL1 that are in contact with the semiconductor patterns SP, the second capacitor electrodes EL2 that pass through the first capacitor electrodes EL1 in the third direction DR3 perpendicular to the substrate, and the dielectric layers DL that are interposed between the first capacitor electrodes EL1 and the second capacitor electrodes EL2.

The first capacitor electrodes EL1 may have the form of pillars surrounded by the side walls, and the side walls of the first capacitor electrodes EL1 and the second side surfaces of the semiconductor patterns SP may be in contact with each other. The first capacitor electrodes EL1 may have a hollow pillar shape. The second capacitor electrodes EL2 may extend in the third direction DR3 through the interior spaces of the first capacitor electrodes EL1. The first capacitor electrodes EL1 may be formed so as to surround the dielectric layers DL and the second capacitor electrodes EL2.

The semiconductor device may include the word lines WL and the bit line connection portions BLC that extend through the plurality of layers of the stack structure SS in the direction perpendicular to the substrate. The semiconductor device may include upper and lower wiring layers, and one of the upper and lower wiring layers may be connected to the word lines WL, and the other may be connected to the bit line connection portions BLC. Accordingly, it is possible to reduce the areas on the substrate which are separately occupied by the wiring layer that is connected to the bit lines BL and the wiring layer connected to the word lines WL, thereby increasing the degree of integration of the semiconductor device.

The semiconductor device may include the word line protrusions WL_P. Since it is possible to further use the upper surfaces of the semiconductor patterns SP facing the word line protrusions WL_P as well as the third side surfaces of the semiconductor patterns SP facing the word lines WL as channel regions, it is possible to increase the areas usable as channels.

Hereinafter, another example of the word line structures WLS of the semiconductor device of FIGS. 1 and 2 will be described with reference to FIG. 3. Specifically, a semiconductor device of FIG. 3 is different from the semiconductor device of FIGS. 1 and 2 only in the structure and shape of the word line protrusions WL_P, and the other components thereof may be identical to those in the semiconductor device of FIGS. 1 and 2. Hereinafter, for convenience, the differences will be described mainly, and contents redundant to the contents described above with reference to FIGS. 1 and 2 may not be described or simplified.

Referring to FIG. 3, the word lines WL may extend in the third direction DR3 perpendicular to the substrate. The word lines WL may face the surfaces of the semiconductor patterns SP perpendicular to the substrate. For example, the word lines WL may face the third side surfaces of the semiconductor patterns SP.

The word line protrusions WL_P may protrude from the word lines WL in the first direction DR1 parallel with the substrate. The word line protrusions WL_P may face the surfaces of the semiconductor patterns SP parallel with the substrate. For example, the word lines WL may face the upper surfaces of the semiconductor patterns SP.

In the implementation shown in FIG. 3, the cross-sectional area of each word line protrusion WL_P may increase as the corresponding word line protrusion goes toward a semiconductor pattern SP along the third direction DR3. The cross-sectional area of each word line protrusion WL_P may increase as the corresponding word line protrusion goes toward the upper surface of a semiconductor pattern SP.

The regions of the semiconductor patterns SP facing the word line structures WLS may serve as channels. The third side surfaces of the semiconductor patterns SP facing the word lines WL and the upper surfaces of the semiconductor patterns SP facing the word line protrusions WL_P may be channel regions. In the implementation shown in FIG. 3, the upper surfaces of the semiconductor patterns SP facing the word line protrusions WL_P may be wider than those in the implementation shown in FIG. 2, and accordingly, the channel regions of the semiconductor patterns SP may be widened.

Hereinafter, the planar shape and structure of the memory cells of the semiconductor device will be described with reference to FIG. 4, and the cross-sectional shape and structure of the memory cells of the semiconductor device will be described with reference to FIG. 5. In FIGS. 4 and 5, four layers and four cells in each layer are shown unlike in FIGS. 1 and 2. Although there are the differences in the numbers of layers and cells, the contents described above with reference to FIGS. 1 and 2 may be applied equally or similarly.

Referring to FIGS. 4 and 5, a stack structure SS may include a plurality of layers including first to fourth layers L1, L2, L3, and L4

The first to fourth layers L1, L2, L3, and L4 may be sequentially stacked on a substrate. Hereinafter, the contents described above with respect to the first layer L1 and the second layer L2 may be equally applied to two different layers. The description of one layer may be equally applied to other layers.

In each layer, a plurality of semiconductor patterns SP may be arranged along the first direction DR1. For example, a first semiconductor pattern SP1, a second semiconductor pattern SP2, a third semiconductor pattern SP3, and a fourth semiconductor pattern SP4 may be sequentially arranged along the first direction DR1.

In each layer, a plurality of semiconductor patterns SP that is arranged along the first direction DR1 may be connected to the same bit line structure BLS. The bit line structure BLS may include bit lines BL extending in the first direction DR1. Each of the plurality of semiconductor patterns SP that is arranged along the first direction DR1 may be connected to one side of a bit line BL. For example, each of the first semiconductor pattern SP1, the second semiconductor pattern SP2, the third semiconductor pattern SP3, and the fourth semiconductor pattern SP4 may be connected to one side of a bit line BL.

Meanwhile, each of the first semiconductor pattern SP1, the second semiconductor pattern SP2, the third semiconductor pattern SP3, and the fourth semiconductor pattern SP4 may extend in the second direction DR2 from one side surface of a bit line BL.

The bit line structure BLS may include bit line protrusions BL_P that protrude in the second direction DR2 from the bit lines BL. The bit line protrusions BL_P may extend in the second direction DR2 from the surfaces of the bit lines BL facing the contact surfaces between the bit lines and the semiconductor patterns SP. The semiconductor patterns SP and the bit line protrusions BL_P may be positioned on both sides with respect to the bit lines BL. The planar shape of the bit line protrusions BL_P may be, for example, a rectangular shape, but is not limited thereto.

The bit lines BL that are included in the plurality of layers, respectively, may overlap in the third direction DR3. Referring to FIG. 5, a first bit line BL1 included in the first layer L1, a second bit line BL2 included in the second layer L2, a third bit line BL3 included in the third layer L3, and a fourth bit line BL4 included in the fourth layer L4 may overlap in the third direction DR3. Accordingly, in FIG. 4, the fourth bit line BL4 included in the fourth layer L4 is positioned on top of the first layer L1 to the fourth layer L4 may be shown.

The bit line protrusions BL_P that are included in the plurality of layers, respectively, may not overlap in the third direction DR3. Referring to FIG. 4, first bit line protrusions BL_P1 included in the first layer L1, second bit line protrusions BL_P2 included in the second layer L2, third bit line protrusions BL_P3 included in the third layer L3, and fourth bit line protrusions BL_P4 included in the fourth layer L4 may be disposed so as not to overlap plane-wise.

Meanwhile, in FIG. 5, since insulating layers are omitted, the first bit line protrusions BL_P1, the second bit line protrusions BL_P2, the third bit line protrusions BL_P3, and the fourth bit line protrusions BL_P4 may look like overlapping in the third direction DR3; however, they may not actually overlap in the third direction DR3.

Referring to FIG. 4, a first bit line protrusion BL_P1, a second bit line protrusion BL_P2, a third bit line protrusion BL_P3, and a fourth bit line protrusion BL_P4 may be arranged along the first direction DR1 on a plane. The plurality of bit line protrusions BL_P may be disposed in regions which overlap regions where the plurality of semiconductor patterns SP is arranged along the first direction DR1 plane-wise in the second direction DR2.

Bit line connection portions BLC may extend in the third direction DR3 from the bit line protrusions BL_P. The planar shape of the bit line connection portions BLC may be, for example, a circular shape, but is not limited thereto. As another example, it may be a polygonal shape such as a rectangular shape.

The bit line connection portions BLC may pass through the bit line protrusions BL_P in the third direction DR3. A first bit line connection portion BLC1 may extend through the first bit line protrusions BL_P1, and a second bit line connection portion BLC2 may extend through the second bit line protrusions BL_P2, and a third bit line connection portion BLC3 may extend through the third bit line protrusions BL_P3, and a fourth bit line connection portion BLC4 may extend through the fourth bit line protrusions BL_P4.

Referring to FIG. 4, the first bit line connection portion BLC1, the second bit line connection portion BLC2, the third bit line connection portion BLC3, and the fourth bit line connection portion BLC4 may be disposed so as not to overlap plane-wise. The first bit line connection portion BLC1, the second bit line connection portion BLC2, the third bit line connection portion BLC3, and the fourth bit line connection portion BLC4 may be arranged along the first direction DR1 on a plane. The plurality of bit line connection portions BLC may be disposed in regions which overlap regions where a plurality of semiconductor patterns SP is arranged along the first direction DR1 plane-wise in the second direction DR2.

The semiconductor device may include the bit line protrusions BL_P that extend in the second direction DR2 intersecting with the first direction DR1 in which the bit lines BL that are in contact with the semiconductor patterns SP extend, and the bit line connection portions BLC and the bit lines BL may be connected to each other by the bit line protrusions BL_P. A plurality of bit line protrusions BL_P that is arranged in the third direction DR3 may be disposed so as not to overlap in the third direction DR3.

In a semiconductor device according to a comparative example, a plurality of bit lines BL that is arranged in the third direction DR3 may extend to different lengths in the first direction DR1, such that a step is formed, and surfaces exposed due to the step and a wiring layer may be vertically connected. In this case, an area on the substrate which is occupied by the region where the bit lines BL extend to be connected to the wiring layer may increase in proportion to the number of cells that are stacked.

According to the semiconductor device, a plurality of bit lines BL that is arranged along the third direction DR3 may be extended in the second direction DR2 substantially by the same length, so as to form the bit line protrusions BL_P, and the plurality of bit lines BL and the wiring layer may be connected via the bit line connection portions BLC extending in the third direction DR3 from the bit line protrusions BL_P. Accordingly, the area on the substrate which is occupied by the region where the bit lines BL extend to be connected to the wiring layer corresponds to the length of the bit line protrusions BL_P. Therefore, even if the number of cells that are stacked increases, the above-mentioned area may not increase. The semiconductor device can reduce the area on the substrate which is occupied by the region where the bit lines BL extend to be connected to the wiring layer as compared to the semiconductor device of the comparative example. Therefore, it is possible to improve the degree of integration of the semiconductor device.

Referring to FIG. 4, in each layer, a plurality of word line structures WLS may be disposed. For example, the plurality of word line structures WLS may include a first word line structure WLS1 adjacent to the first semiconductor pattern SP1, a second word line structure WLS2 adjacent to the second semiconductor patterns SP2, a third word line structure WLS3 adjacent to the third semiconductor patterns SP3, and a fourth word line structure WLS4 adjacent to the fourth semiconductor patterns SP4.

The word line structures WLS may include word lines WL that extend in the third direction DR3. The word lines WL may overlap the semiconductor patterns SP in the first direction DR1. Each semiconductor pattern SP may have an upper surface, a lower surface, and four side surfaces, and the four side surfaces may include a first side surface and a second side surface facing each other in the second direction DR2, and a third side surface and a fourth side surface facing each other in the first direction DR1. For example, the word lines WL may face the third side surfaces of the semiconductor patterns SP in the first direction DR1.

Referring to FIG. 5, each word line WL may extend through the plurality of layers. Each word line WL may extend in the third direction DR3 while facing the third side surfaces of a plurality of semiconductor patterns SP that is arranged along the third direction DR3. For example, the word line WL of the first word line structure WLS1 may extend in the third direction DR3 while facing the third side surfaces of the first semiconductor patterns SP1 that are included in the first layer L1 to the fourth layer L4, respectively.

Referring to FIG. 4, the word line structures WLS may include word line protrusions WL_P that protrude in the first direction DR1 from the word lines WL. The planar shape of the word line protrusions WL_P may be, for example, a rectangular shape, but is not limited thereto.

Referring to FIG. 5, the word line protrusions WL_P may protrude from the surfaces of the word lines WL facing the semiconductor patterns SP so as to face the upper surfaces of the semiconductor patterns SP. The word line protrusions WL_P may overlap the semiconductor patterns SP in the third direction DR3.

To one word line WL, a plurality of word line protrusions WL_P may be connected. The word line WL may extend through the plurality of layers. The plurality of word line protrusions WL_P may protrude from one word line WL passing through the plurality of layers, and extend above the upper surfaces of the semiconductor patterns SP that are included in the plurality of layers, respectively. The plurality of word line protrusions WL_P may face the upper surfaces of the semiconductor patterns SP that are included in the plurality of layers, respectively.

Referring to FIG. 5, the first word line structure WLS1 may include a word line WL, a first word line protrusion WL_P1, a second word line protrusion WL_P2, a third word line protrusion WL_P3, and a fourth word line protrusion WL_P4. The word line WL may extend through the first layer L1 to the fourth layer L4. The first word line protrusion WL_P1 may extend above the upper surface of the first semiconductor pattern SP1 included in the first layer L1. The first word line protrusion WL_P1 may face the upper surface of a first semiconductor pattern SP1 included in the first layer L1. The second word line protrusion WL_P2 may extend above the upper surface of the first semiconductor pattern SP1 included in the second layer L2. The second word line protrusion WL_P2 may face the upper surface of the first semiconductor pattern SP1 included in the second layer L2. The third word line protrusion WL_P3 may extend above the upper surface of the first semiconductor pattern SP1 included in the third layer L3. The third word line protrusion WL_P3 may face the upper surface of the first semiconductor pattern SP1 included in the third layer L3. The fourth word line protrusion WL_P4 may extend above the upper surface of the first semiconductor pattern SP1 included in the fourth layer L4. The fourth word line protrusion WL_P4 may face the upper surface of the first semiconductor pattern SP1 included in the fourth layer L4.

The word line structures WLS of the semiconductor device may include the word lines WL that face side surfaces of the semiconductor patterns SP, and the word line protrusions WL_P that protrude in the first direction DR1 from the word lines WL so as to face the upper surfaces of the semiconductor patterns SP. The semiconductor device can further use the upper surfaces of the semiconductor patterns SP facing the word line protrusions WL_P as well as the side surfaces of the semiconductor patterns SP facing the word lines WL as channel regions. Therefore, it is possible to increase the areas usable as channels.

Referring to FIGS. 4 and 5, the semiconductor patterns SP may be in contact with the side walls of the first capacitor electrodes EL1 of the capacitors CP. The first capacitor electrodes EL1 of the capacitors CP may have the form of pillars surrounded by the side walls. The second capacitor electrodes EL2 may pass through the interior spaces of the first capacitor electrodes EL1 in the third direction DR3. The dielectric layers DL may be interposed between the first capacitor electrodes EL1 and the second capacitor electrodes EL2. The first capacitor electrodes EL1 may surround the dielectric layers DL and the second capacitor electrodes EL2.

Capacitors CP that are included in the plurality of layers, respectively, and overlap in the third direction DR3 may share one second capacitor electrode EL2. Referring to FIG. 5, a first capacitor CP1 that is included in the first layer L1, a second capacitor CP2 that is included in the second layer L2, a third capacitor CP3 that is included in the third layer L3, and a fourth capacitor CP4 that is included in the fourth layer L4 may share one second capacitor electrode EL2 extending in the third direction DR3 through the first layer L1 to the fourth layer L4.

For example, the side wall of the second capacitor electrode EL2 that extend in the third direction DR3 between the first capacitor CP1 and the second capacitor CP2 may be surrounded by dielectric layers DL and a dummy electrode EL1_D. The dummy electrode EL1_D may be electrically insulated from the first capacitor electrode EL1 of the first capacitor CP1 and the first capacitor electrode EL1 of the second capacitor CP2. The dummy electrode EL1_D may have widths (a width in the first direction DR1 and a width in the second direction DR2) smaller than those of the first capacitor electrode EL1 of the first capacitor CP1 and the first capacitor electrode EL1 of the second capacitor CP2. The dummy electrode EL1_D may be in contact with the dielectric layer DL of the first capacitor CP1 and the dielectric layer DL of the second capacitor CP2.

Hereinafter, a structure in which bit line structures BLS and word line structures WLS of a semiconductor device according to some implementations of the present disclosure are connected to wiring layers will be described with reference to FIGS. 6 and 7.

FIG. 6 is a cross-sectional view illustrating an example of a semiconductor device.

Referring to FIG. 6, in a semiconductor device, a core region CR and a cell region CLR may be defined on the front surface of a substrate 110, and a peripheral region PR may be defined on the back surface of the substrate 110. The core region CR and the cell region CLR may be stacked in the third direction DR3 on the front surface of the substrate 110. The peripheral region PR may be positioned on the back surface of the substrate 110. The peripheral region PR may be separated from the core region CR by the substrate 110.

The substrate 110 may be a semiconductor substrate containing a semiconductor material. For example, the substrate 110 may contain silicon, germanium, silicon-germanium, silicon on insulator (SOI), or germanium on insulator (GOI).

Circuit elements CE that are formed on the front surface and back surface of the substrate 110 may include various circuit elements for controlling the operation of a memory cell structure (for example, a stack structure SS) provided in the cell region CLR. The circuit elements CE may include, for example, transistors, but are not limited thereto. For example, the circuit elements CE may include not only active elements such as transistors but also passive elements such as capacitors, resistors, inductors, and the like.

When the circuit elements CE are transistors, the circuit elements CE may be planar metal oxide semiconductor field effect transistors (MOSFETs), fin field effect transistors (FinFETs), recess gate transistors, gate all around (GAA) transistors, or multi-bridge channel field effect transistors (MBCFETs wherein MBCFET is a trademark), but are not limited thereto. Alternatively, the circuit elements CE may consist of 3D stack field effect transistors (3DSFETs), complementary field effect transistors (CFETs), and the like to which a next generation technology has been applied.

The core region CR may include the circuit elements CE, a lower wiring layer 122 that is connected to the circuit elements CE, and a lower inter-wiring insulating layer 120 that covers the circuit elements CE and the lower wiring layer 122. The lower wiring layer 122 may contain various conductive materials, and the lower inter-wiring insulating layer 120 may contain various insulating materials.

On the core region CR, the cell region CLR may be positioned. The cell region CLR may include a stack structure SS. The stack structure SS is a structure including a plurality of memory cells stacked in three dimensions, and the contents described above with reference to FIGS. 1 to 5 may be equally applied. The stack structure SS may be covered by a cell insulating layer 140.

Each of a plurality of bit line structures BLS may include bit lines BL that extend in the first direction DR1, and bit line protrusions BL_P that protrude in the second direction DR2 from the bit lines BL. The plurality of bit line structures BLS may be connected to the lower wiring layer 122 by a plurality of bit line connection portions BLC extending in the third direction DR3, respectively. Each of the plurality of bit line connection portions BLC may extend through the plurality of layers of the stack structure SS, and be connected to a bit line structure BLS of one layer of the plurality of layers. Each of the plurality of bit line connection portions BLC may pass through a lower insulating layer 130 positioned between the cell region CLR and the core region CR and be connected to the lower wiring layer 122. The bit line connection portions BLC may be through-vias that connect the bit line structures BLS and the lower wiring layer 122.

Each of a plurality of word line structures WLS may include a word line WL that extends in the third direction DR3, and a plurality of word line protrusions WL_P that protrudes in the first direction DR1 from the word line WL. Each of the plurality of word lines WL may extend through the plurality of layers of the stack structure SS, and each word line WL may connect a plurality of word line protrusions WL_P which is included in the plurality of layers, respectively, and is arranged along the third direction DR3. Each of the plurality of word lines WL may pass through an upper insulating layer 150 positioned between the cell region CLR and an upper inter-wiring insulating layer 160, and be connected to an upper wiring layer 162. The word lines WL may be through-vias that connect the word line structures WLS and the upper wiring layer 162.

The upper wiring layer 162 may be connected to the core region CR and the peripheral region PR by first pass-through plugs 182. The first pass-through plugs 182 may pass through the upper inter-wiring insulating layer 160, the upper insulating layer 150, the cell insulating layer 140, the lower insulating layer 130, and the lower inter-wiring insulating layer 120, and be connected to the circuit elements CE of the core region CR and contact portions 192 and 194. The contact portions 192 and 194 may pass through the substrate 110 and be connected to the circuit elements CE of the peripheral region PR. For example, a signal that is transmitted from the core region CR may be transferred to the word line structures WLS through the first pass-through plugs 182, the upper wiring layer 162, and the word lines WL. A signal that is transmitted from the peripheral region PR may be transferred to the word line structures WLS through the contact portions 192 and 194, the first pass-through plugs 182, the upper wiring layer 162, and the word lines WL.

The upper wiring layer 162 may be connected to the plurality of capacitors CP through capacitor contacts 172. The upper wiring layer 162 may be connected to the peripheral region PR by second pass-through plugs 184. The second pass-through plugs 184 may pass through the upper inter-wiring insulating layer 160, the upper insulating layer 150, the cell insulating layer 140, the lower insulating layer 130, the lower inter-wiring insulating layer 120, and the substrate 110, and be connected to the circuit elements CE of the peripheral region PR. For example, power may be supplied from the peripheral region PR to the capacitors CP through the second pass-through plugs 184, the upper wiring layer 162, and the capacitor contacts 172.

The peripheral region PR may include the circuit elements CE, a peripheral wiring layer 212 that is connected to the circuit elements CE, and a peripheral inter-wiring insulating layer 210 that covers the circuit elements CE and the peripheral wiring layer 212. The peripheral wiring layer 212 may contain various conductive materials, and the peripheral inter-wiring insulating layer 210 may contain various insulating materials.

The substrate 110 may include first contact portions 192 and second contact portions 194. The first contact portions 192 may extend from the front surface of the substrate 110 to the middle between the front surface and back surface of the substrate 110. The second contact portions 194 may extend from the back surface of the substrate 110 to the middle between the front surface and back surface of the substrate 110. The second contact portions 194 may be formed so as to be aligned with the first contact portions 192 and connected to the first contact portions 192 in the third direction DR3.

The first contact portions 192 and the second contact portions 194 may connect the core region CR and the peripheral region PR. The first contact portions 192 may be connected to the lower wiring layer 122 and the first pass-through plugs 182. The second contact portions 194 may be connected to the peripheral wiring layer 212. The peripheral wiring layer 212 may be connected to the upper wiring layer 162 through the second pass-through plugs 184.

The semiconductor device may include the word lines WL and the bit line connection portions BLC that extend in the third direction DR3 perpendicular to the substrate 110. The word lines WL may pass through the plurality of layers of the stack structure SS and the upper insulating layer 150 and be connected to the upper wiring layer 162. The bit line connection portions BLC may pass through the plurality of layers of the stack structure SS and the lower insulating layer 130 and be connected to the lower wiring layer 122. The word lines WL may pass through the upper insulating layer 150 without passing through the lower insulating layer 130. The bit line connection portions BLC may pass through the lower insulating layer 130 without passing through the upper insulating layer 150. Accordingly, it is possible to provide the semiconductor device in which the wiring layer that is connected to the word line structures WLS and the wiring layer that is connected to the bit line structures BLS are separated vertically. The wiring layer that is connected to the bit line structures BLS and the wiring layer that is connected to the word line structures WLS may be stacked in the direction perpendicular to the substrate 110, whereby it is possible to reduce the area on the substrate 110 which is separately occupied by the two wiring layers. Therefore, it is possible to increase the degree of integration of the semiconductor device.

FIG. 7 is a cross-sectional view illustrating an example of core/peripheral regions of the semiconductor device. The semiconductor device of FIG. 7 may be partially different from the semiconductor device of FIG. 6 only in the structure of a core/peripheral region, and the other components thereof may be identical to those in the semiconductor device of FIG. 6. Hereinafter, descriptions that are redundant to the description of FIG. 6 will not be made or simplified.

Referring to FIG. 7, in a semiconductor device, a core/peripheral region CPR and a cell region CLR may be defined on the upper surface of a substrate 110. The core/peripheral region CPR and the cell region CLR may be stacked in the third direction DR3 on the upper surface of the substrate 110. Unlike in FIG. 6, a core region and a peripheral region may be positioned together between the substrate 110 and the cell region CLR.

The core/peripheral region CPR may include circuit elements CE, a lower wiring layer 312 that is connected to the circuit elements CE, and a lower inter-wiring insulating layer 310 that covers the circuit elements CE and the lower wiring layer 312. The lower wiring layer 312 may contain various conductive materials, and the lower inter-wiring insulating layer 310 may contain various insulating materials.

On the core/peripheral region CPR, the cell region CLR may be positioned. Each of a plurality of bit line connection portions BLC may pass through the lower inter-wiring insulating layer 310 positioned between the cell region CLR and the core/peripheral region CPR and be connected to the lower wiring layer 312. The bit line connection portions BLC may be through-vias that connect the bit line structures BLS and the lower wiring layer 312.

Each of the plurality of word lines WL may pass through an upper insulating layer 150 positioned between the cell region CLR and an upper inter-wiring insulating layer 160, and be connected to an upper wiring layer 162. The word lines WL may be through-vias that connect the word line structures WLS and the upper wiring layer 162.

The upper wiring layer 162 may be connected to the core/peripheral region CPR by third pass-through plugs 186. The third pass-through plugs 186 may pass through the upper inter-wiring insulating layer 160, the upper insulating layer 150, the cell insulating layer 140, the lower insulating layer 130, and the lower inter-wiring insulating layer 310, and be connected to the lower wiring layer 312 and the circuit elements CE of the core/peripheral region CPR. For example, a signal that is transmitted from the core/peripheral region CPR may be transferred to the word line structures WLS through the third pass-through plugs 186, the upper wiring layer 162, and the word lines WL.

The upper wiring layer 162 may be connected to the plurality of capacitors CP through capacitor contacts 172. The upper wiring layer 162 may be connected to the core/peripheral region CPR by fourth pass-through plugs 188. The fourth pass-through plugs 188 may pass through the upper inter-wiring insulating layer 160, the upper insulating layer 150, the cell insulating layer 140, the lower insulating layer 130, and the lower inter-wiring insulating layer 310, and be connected to the lower wiring layer 312 and the circuit elements CE of the core/peripheral region CPR. For example, power may be supplied from the core/peripheral region CPR to the capacitors CP through the fourth pass-through plugs 188, the upper wiring layer 162, and the capacitor contacts 172.

Like in the implementation of FIG. 6, the semiconductor device of FIG. 7 may include the word lines WL and the bit line connection portions BLC that extend in the third direction DR3 perpendicular to the substrate 110. The word lines WL may pass through the plurality of layers of the stack structure SS and the upper insulating layer 150 and be connected to the upper wiring layer 162. The bit line connection portions BLC may pass through the plurality of layers of the stack structure SS and the lower insulating layer 130 and be connected to the lower wiring layer 312. The word lines WL may pass through the upper insulating layer 150 without passing through the lower insulating layer 130. The bit line connection portions BLC may pass through the lower insulating layer 130 without passing through the upper insulating layer 150. Accordingly, it is possible to provide the semiconductor device in which the wiring layer that is connected to the word line structures WLS and the wiring layer that is connected to the bit line structures BLS are separated vertically. The wiring layer that is connected to the bit line structures BLS and the wiring layer that is connected to the word line structures WLS may be stacked in the direction perpendicular to the substrate 110, whereby it is possible to reduce the area on the substrate 110 which is separately occupied by the two wiring layers. Therefore, it is possible to increase the degree of integration of the semiconductor device.

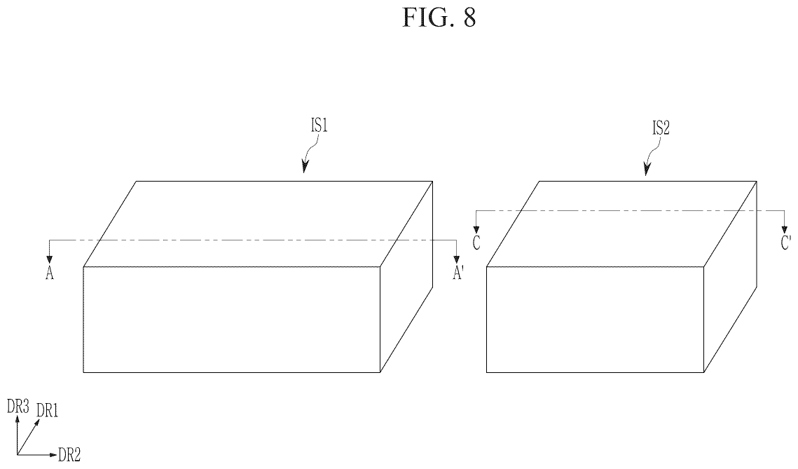

Hereinafter, a method of manufacturing a semiconductor device will be described with reference to FIGS. 8 to 26. According to the method shown in FIGS. 8 to 26, two cells may be formed so as to be stacked in the third direction DR3. In FIGS. 8 to 26, for convenience, a method of forming a portion of a memory cell structure of a semiconductor device is shown; however, the same method or a similar method may be used to form a memory cell structure in which a plurality of cells is arranged in the first direction DR1 and more cells are stacked in the third direction DR3.

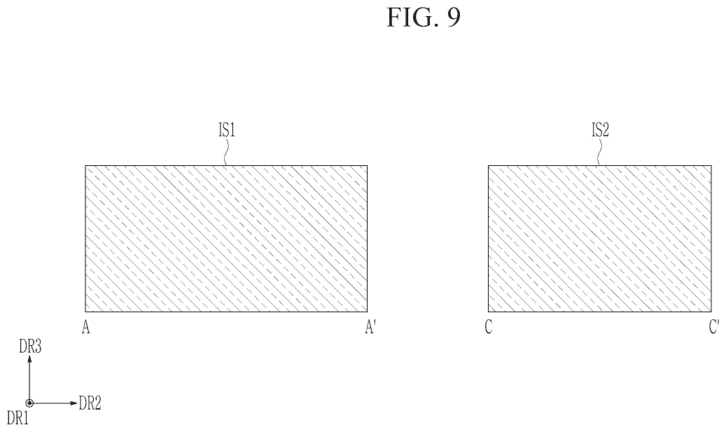

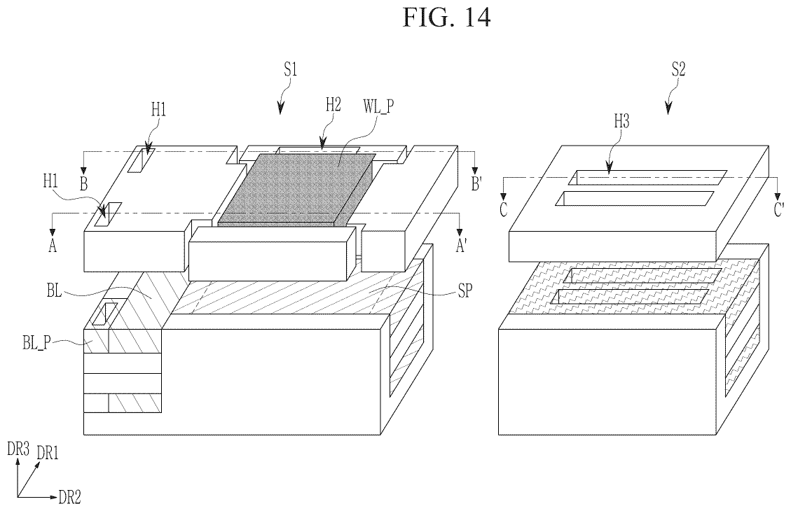

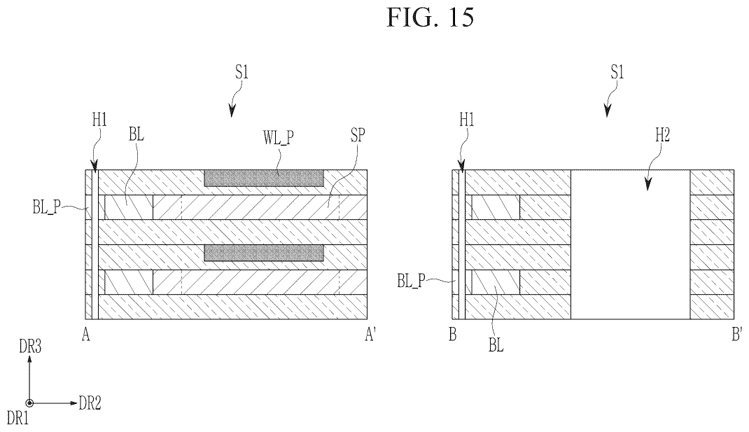

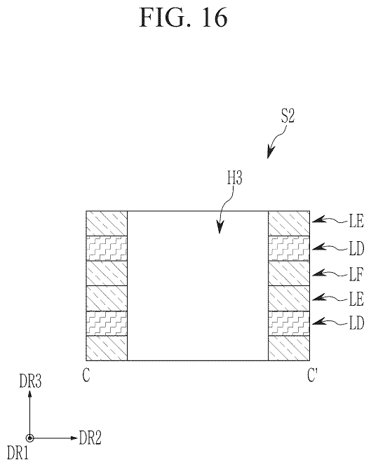

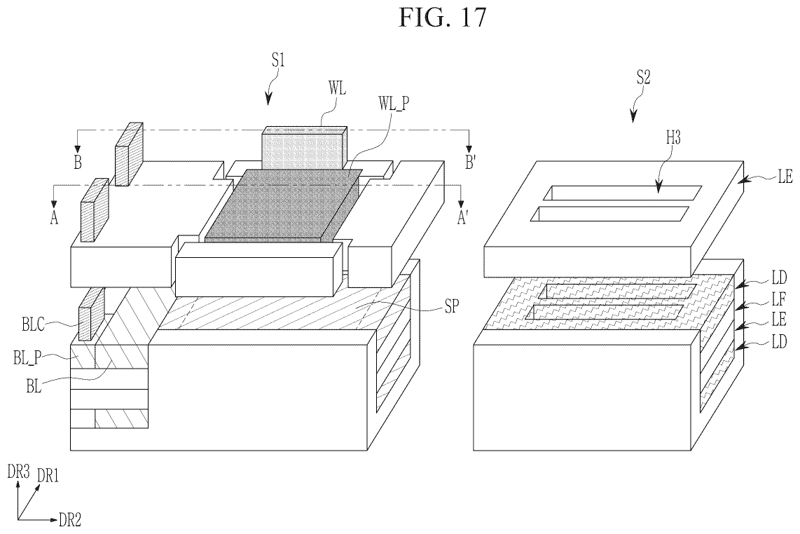

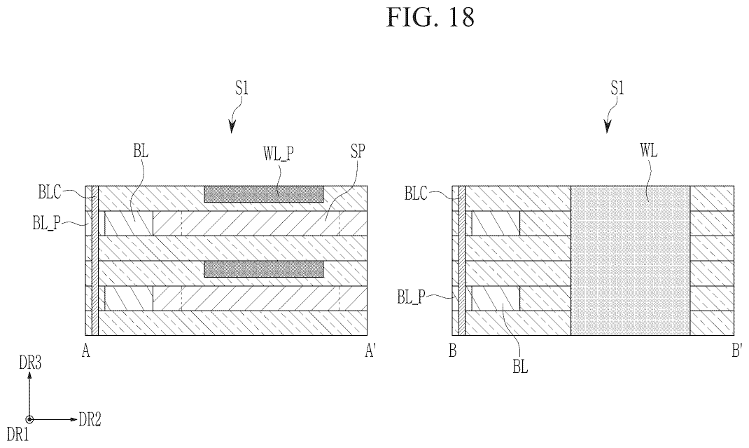

FIGS. 8, 10, 12, 14, 17, 19, 21, 23, and 25 are perspective views illustrating an example of the method of manufacturing a semiconductor device. FIGS. 9, 11, 13, 15, 16, 18, 20, 22, 24, and 26 are example cross-sectional views illustrating the method of manufacturing the semiconductor device. FIGS. 9, 11, and 13 are cross-sectional views taken along lines A-A′ and C-C′ of FIGS. 8, 10, and 12. FIGS. 15 and 18 are cross-sectional views taken along lines A-A′ and B-B′ of FIGS. 14 and 17. FIGS. 16, 20, 22, 24, and 26 are cross-sectional views taken along line C-C′ of FIGS. 14, 19, 21, 23, and 25.

Referring to FIGS. 8 and 9, a first instructing structure IS1 and a second instructing structure IS2 may be prepared. The instructing structures IS1 and IS2 may be provided on a substrate not shown in the drawings.

In the drawings, it is shown that the first instructing structure IS1 and the second instructing structure IS2 are spaced apart from each other; however, they are intentionally shown as being spaced apart from each other only to show the cross section of the first instructing structure IS1, and in practice, the first instructing structure IS1 and the second instructing structure IS2 may be integrally formed. In other words, in the second direction DR2, on one side of the first instructing structure IS1, the second instructing structure IS2 may be positioned, and although not shown in the drawings, on the other side of the first instructing structure IS1, an insulating layer may be positioned. Further, in the second direction DR2, on one side of the second instructing structure IS2, the first instructing structure IS1 may be positioned, and although not shown in the drawings, on the other side of the second instructing structure IS2, an insulating layer may be positioned.

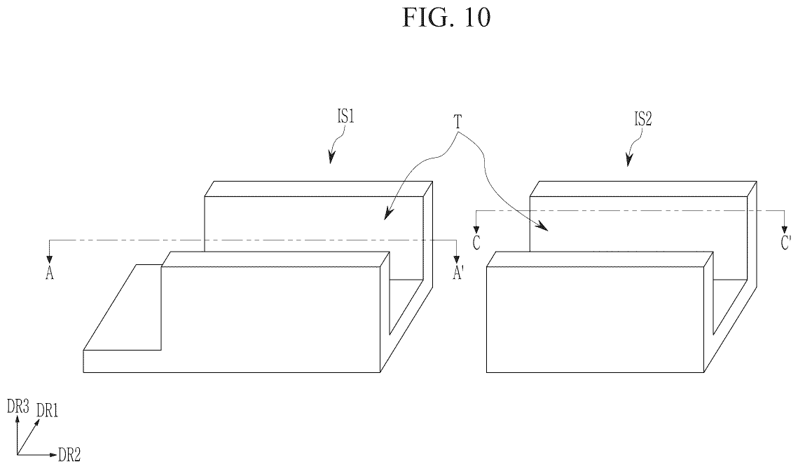

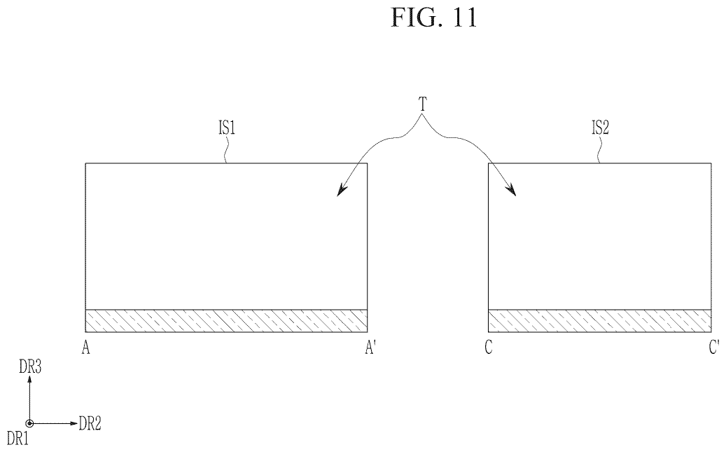

Referring to FIGS. 10 and 11, a trench T may be formed by performing etching on the first instructing structure IS1 and the second instructing structure IS2. The trench T may include a first portion that extends in the first direction DR1, and a second portion that extends in the second direction DR2. The first instructing structure IS1 may include the first portion and a portion of the second portion of the trench T. The second instructing structure IS2 may include the other portion of the second portion.

As will be described below, on the first portion of the trench T, a bit line structure BLS may be formed. In the second portion of the trench T included in the first instructing structure IS1, semiconductor patterns SP and a word line structure WLS may be formed. In the second portion of the trench T included in the second instructing structure IS2, capacitors CP may be formed.

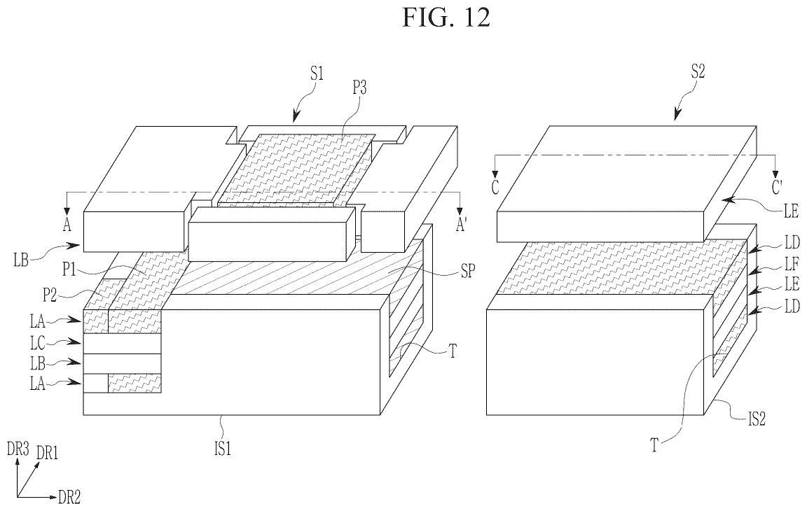

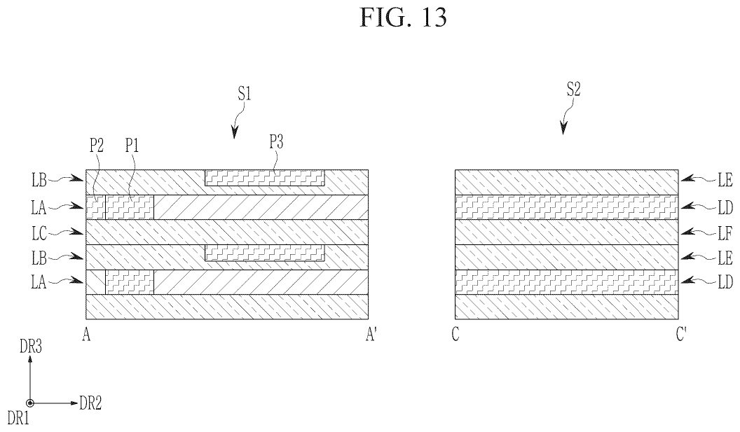

Referring to FIGS. 12 and 13, a plurality of layers may be stacked in the trench T. In the portion of the trench T included in the first instructing structure IS1, a semiconductor layer LA including a semiconductor pattern SP, a gate electrode layer LB in which a portion of a gate electrode is formed, and an insulating layer LC may be sequentially stacked, and this process may be repeated. For example, in the portion of the trench T included in the first instructing structure IS1, a semiconductor layer LA, a gate electrode layer LB, an insulating layer LC, a semiconductor layer LA, a gate electrode layer LB may be sequentially formed.

Each semiconductor layer LA may include a first sacrificial pattern P1 that extends in the first direction DR1, a semiconductor pattern SP that extends in the second direction DR2 from one side of the first sacrificial pattern P1, and a second sacrificial pattern P2 that extends in the second direction DR2 from the opposite side of the first sacrificial pattern P1. Portions of the semiconductor layers LA except for the first sacrificial patterns P1, the second sacrificial patterns P2, and the semiconductor patterns SP may contain an insulating material. When a semiconductor layer LA is formed, the first sacrificial pattern P1 and the second sacrificial pattern P2 may be formed simultaneously; however, the present disclosure is not limited thereto, and the first sacrificial pattern P1 may be formed first, and then the second sacrificial pattern P2 may be formed.

The first sacrificial patterns P1 of the plurality of semiconductor layers LA and the semiconductor patterns SP may be formed so as to overlap in the third direction DR3. The second sacrificial patterns P2 of the plurality of semiconductor layers LA may be formed so as not to overlap in the third direction DR3.

The gate electrode layers LB may include third sacrificial patterns P3 that are positioned on the upper surfaces of the semiconductor patterns SP positioned in the semiconductor layers LA. The third sacrificial patterns P3 may be spaced apart from the bottom surfaces of the gate electrode layers LB. The third sacrificial patterns P3 may have a width equal to or larger than the width of the semiconductor patterns SP in the first direction DR1. The third sacrificial patterns P3 may have a width smaller than the width of the semiconductor patterns SP in the second direction DR2. The other portions of the gate electrode layers LB except for the third sacrificial patterns P3 may contain an insulating material.

The insulating layers LC may contain an insulating material.

The first sacrificial patterns P1, the second sacrificial patterns P2, and the third sacrificial patterns P3 may contain, for example, silicon nitride, but are not limited thereto. The semiconductor patterns SP may contain a semiconductor material, for example, silicon, but are not limited thereto.

As described above, the portions of the individual layers except for the patterns and the insulating layers LC may contain an insulating material. The insulating material may contain a material having etch selectivity to the first sacrificial patterns P1, the second sacrificial patterns P2, and the third sacrificial patterns P3, for example, silicon oxide, but is not limited thereto.

In the portion of the trench T included in the second instructing structure IS2, a sacrificial layer LD, a first insulating layer LE, and a second insulating layer LF may be sequentially stacked, and this process may be repeated. For example, in the portion of the trench T included in the second instructing structure IS2, a sacrificial layer LD, a first insulating layer LE, a second insulating layer LF, a sacrificial layer LD, and a first insulating layer LE may be sequentially formed. The sacrificial layers LD may contain, for example, silicon nitride, but are not limited thereto. A first insulating layer LE and a second insulating layer LF may contain the same insulating material, and may be integrally formed. The first insulating layers LE and the second insulating layers LF may contain a material having etch selectivity to the sacrificial layers LD, for example, silicon oxide, but are not limited thereto.

Hereinafter, the first instructing structure IS1 including the plurality of layers formed in the trench T may be referred to as a first structure S1. The second instructing structure IS2 including the plurality of layers formed in the trench T may be referred to as a second structure S2.

Referring to FIGS. 14 to 16, the sacrificial patterns P1, P2, and P3 of the first structure S1 may be replaced with conductive patterns, and through-holes H1, H2, and H3 may be formed in the first structure S1 and the second structure S2. Further, both end portions of each semiconductor pattern SP may be doped with impurities.

For example, the sacrificial patterns P1, P2, and P3 may be removed by selective etching, to form conductive patterns. The conductive patterns may contain a conductive material. The conductive material may be, for example, any one of doped semiconductor materials such as doped silicon or doped germanium, conductive metal nitrides such as titanium nitride or tantalum nitride, metals such as tungsten, titanium, or tantalum, or metal-semiconductor compounds such as tungsten silicide, cobalt silicide, or titanium silicide.

A conductive pattern replacing a first sacrificial pattern P1 may be a bit line BL. A conductive pattern replacing a second sacrificial pattern P2 may be a bit line protrusion BL_P. A conductive pattern replacing a third sacrificial pattern P3 may be a word line protrusion WL_P.

The word line protrusions WL_P may be spaced apart from the upper surfaces of the semiconductor pattern SP. Between the lower surfaces of the word line protrusions WL_P and the upper surfaces of the semiconductor patterns SP, gate insulating layers may be positioned.

Subsequently, the through-holes H1, H2, and H3 may be formed so as to pass through the first structure S1 and the second structure S2 in the third direction DR3. The first through-holes H1 and the second through-hole H2 may pass through the first structure S1, and the third through-hole H3 may pass through the second structure S2.

Each of the first through-holes H1 may be formed so as to pass through bit line protrusions BL_P. The second through-hole H2 may be formed so as to pass through the insulating layers, each of which is positioned on one side surface of the side surfaces of a corresponding semiconductor pattern SP facing each other in the first direction DR1. The second through-hole H2 may be spaced apart from the side surfaces of the semiconductor patterns SP. The second through-hole H2 may be in contact with the word line protrusions WL_P in the first direction DR1. The inner wall of second through-hole H2 may include one surface of each of the word line protrusions WL_P.

The third through-holes H3 may be formed so as to pass through near the center of the second structure S2 in a plan view. In FIG. 14, the number of third through-holes H3 is two; however, the number of third through-holes H3 is not limited thereto.

Referring to FIGS. 17 and 18, conductive patterns may be formed by filling the first through-holes H1 and the second through-hole H2 with conductive materials. Each conductive material may be, for example, any one of doped semiconductor materials, conductive metal nitrides, metals, or metal-semiconductor compounds. For example, the conductive material that is filled in the first through-holes H1 may be the same conductive material as that in the bit line BL and the bit line protrusions BL_P of FIGS. 14 and 15. For example, the conductive material that is filled in the second through-hole H2 may be the same conductive material as that in the word line protrusions WL_P of FIGS. 14 and 15.

The conductive patterns formed in the first through-holes H1 may be bit line connection portions BLC. The bit line connection portions BLC may extend through the bit line protrusions BL_P in the third direction DR3, respectively.

The conductive pattern formed in the second through-hole H2 may be a word line WL. The word line WL may be formed so as to face one side surface of the side surfaces of each of the semiconductor patterns SP facing each other in the first direction DR1. Although not shown in the drawings, between the surfaces of the semiconductor patterns SP and the word line WL facing each other, gate insulating layers may be positioned.

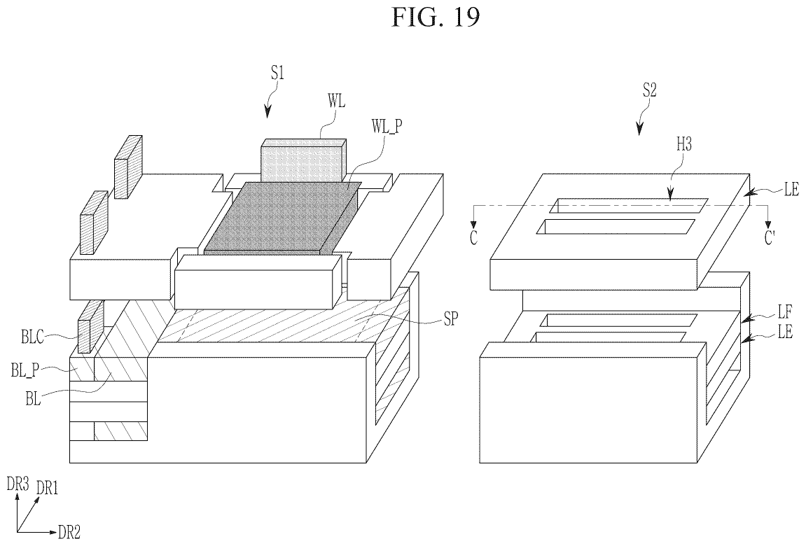

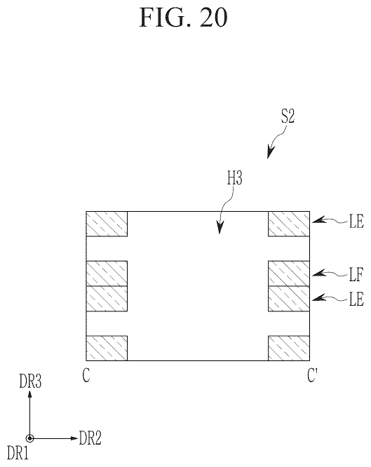

Referring to FIGS. 19 and 20, the sacrificial layers LD may be removed. For example, the sacrificial layers LD may be removed by performing selective etching through the third through-holes H3. The sacrificial layers LD may be removed such that some portions of the upper surfaces or lower surfaces of the insulating layers LE and LF are exposed.

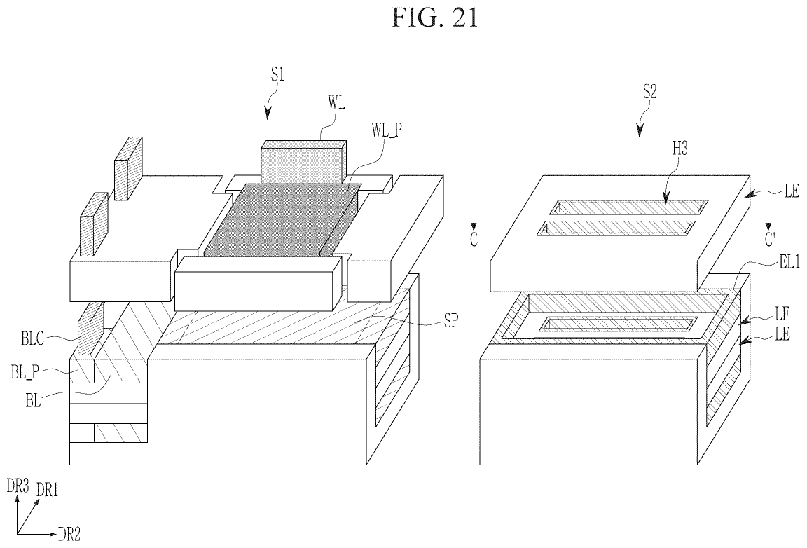

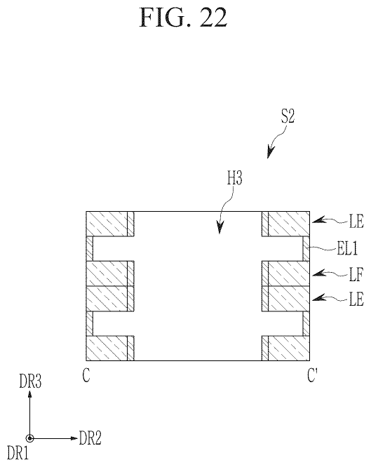

Referring to FIGS. 21 and 22, first capacitor electrodes EL1 may be formed by depositing a conductive material. The conductive material may contain, for example, at least one of metal materials, conductive metal nitrides, or doped semiconductor materials.

The first capacitor electrodes EL1 may be formed on the inner surfaces of the third through-holes H3 extending in a direction perpendicular to the substrate (for example, the third direction DR3). The first capacitor electrodes EL1 may not be formed on the inner surfaces of the third through-holes H3 extending in directions parallel with the substrate (for example, the first direction DR1 and the second direction DR2).

For example, after the conductive material is deposited so as to conform to the inner walls of the third through-holes H3, the conductive material deposited on the surfaces of the inner walls of the third through-holes H3 parallel with the substrate may be etched. Accordingly, the plurality of first capacitor electrodes EL1 may be formed so as to be separated in the third direction DR3, and the plurality of first capacitor electrodes EL1 may be formed so as to conform to the surfaces of the inner walls of the third through-holes H3 perpendicular to the substrate. Each of the plurality of first capacitor electrodes EL1 may have the form of a hollow pillar surrounded by a side wall.

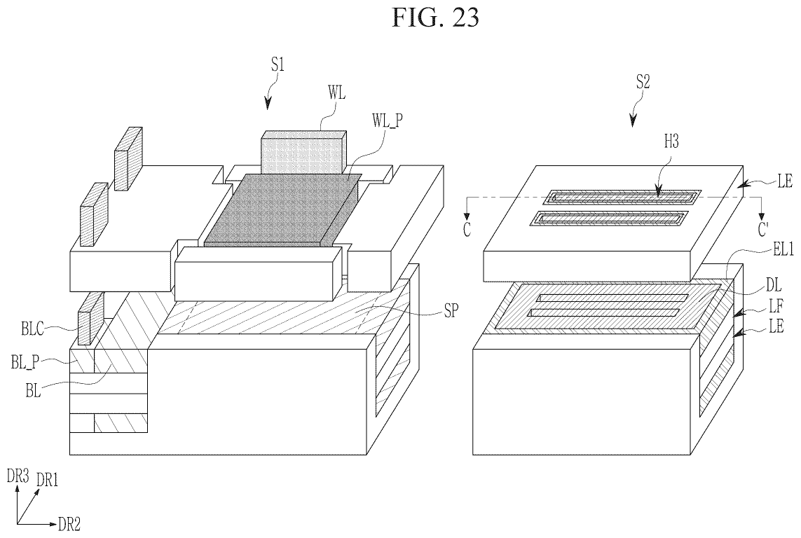

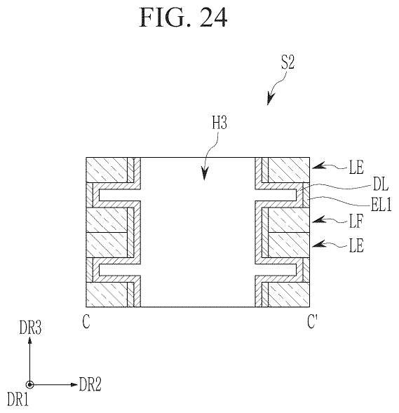

Referring to FIGS. 23 and 24, a dielectric layer DL may be formed. The dielectric layer DL may contain a high-dielectric constant material. The high-dielectric constant material may contain, for example, hafnium oxide, hafnium silicon oxide, zirconium oxide, zirconium silicon oxide, aluminum oxide, lanthanum oxide, tantalum oxide, titanium oxide, barium strontium titanium oxide, strontium titanium oxide, lithium oxide, lead scandium tantalum oxide, lead zinc niobate, or a combination thereof.

Dielectric layers DL may be formed on the inner walls of the third through-holes H3 so as to conform to the inner walls. The dielectric layers DL may cover the plurality of first capacitor electrodes EL1 formed on the surfaces of the inner walls of the third through-holes H3 perpendicular to the substrate. The dielectric layers DL may cover the surfaces of the insulating layers LE and LF corresponding to the surfaces of the inner walls of the third through-holes H3 parallel with the substrate.

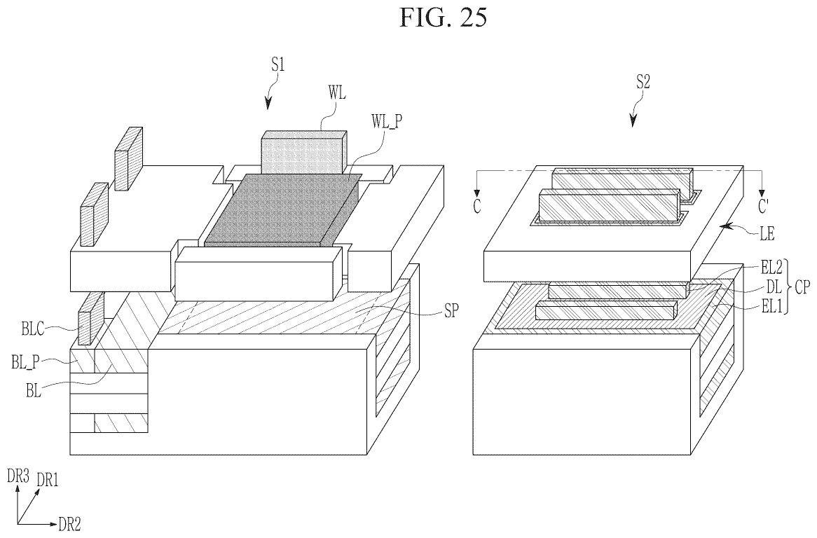

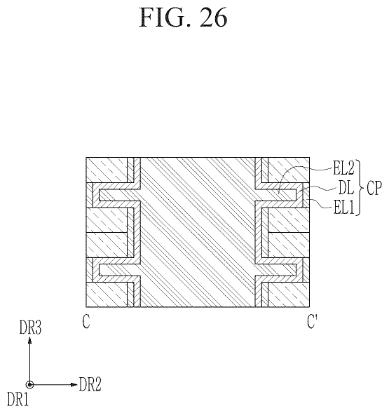

Referring to FIGS. 25 and 26, second capacitor electrodes EL2 may be formed by filling the remaining spaces in the third through-holes H3 with a conductive material. The conductive material may contain, for example, at least one of metal materials, conductive metal nitrides, or doped semiconductor materials.

In FIG. 25, since the number of third through-holes H3 is two, two separate second capacitor electrodes EL2 may be formed; however, they may serve as one electrode.

The second capacitor electrodes EL2 may extend through the second structure S2 in the third direction DR3. As the second capacitor electrodes EL2 are formed, the plurality of capacitors CP may be formed so as to overlap in the third direction DR3. The plurality of capacitors CP that overlaps in the third direction DR3 may share one second capacitor electrode EL2 extending in the third direction DR3.

The first capacitor electrodes EL1 of the plurality of capacitors CP overlapping in the third direction DR3 may be insulated by the dielectric layers DL formed on the surfaces of the inner walls of the third through-holes H3 parallel with the substrate.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical implementations, it is to be understood that the disclosure is not limited to the disclosed implementations. On the contrary, it is intended to cover various modifications and equivalent arrangements included within the spirit and scope of the appended claims.

What is claimed is:

1. A semiconductor device comprising:
a stack structure including a plurality of layers stacked on a substrate,
wherein each layer of the plurality of layers includes:
a bit line structure that includes a bit line, the bit line extending in a first direction parallel with the substrate;
a bit line connection portion that connects the bit line structure and a wiring layer, the bit line connection portion extending in a third direction perpendicular to the substrate;
a semiconductor pattern that is electrically connected to the bit line, the semiconductor pattern extending in a second direction intersecting with the first direction;
a word line structure that includes a word line and a word line protrusion, the word line extending in the third direction, the word line protrusion protruding in the first direction from the word line; and
a capacitor that is electrically connected to the semiconductor pattern, and
wherein the word line faces a first surface of the semiconductor pattern perpendicular to the substrate, and
wherein the word line protrusion faces a second surface of the semiconductor pattern parallel with the substrate.

2. The semiconductor device of claim 1, wherein
the bit line structure includes a bit line protrusion that protrudes in the second direction from the bit line, and
the bit line connection portion extends through the bit line protrusion.

3. The semiconductor device of claim 1, wherein
the bit line connection portion and the word line are connected to two respective wiring layers, the two wiring layers positioned in two directions opposite to each other.

4. The semiconductor device of claim 3, wherein
the bit line connection portion is connected to a lower wiring layer, the lower wiring layer positioned between the substrate and the stack structure.

5. The semiconductor device of claim 3, wherein
the word line is connected to an upper wiring layer, the upper wiring layer positioned on the stack structure.

6. The semiconductor device of claim 1, comprising:
a plurality of semiconductor patterns positioned along the third direction, wherein
each semiconductor pattern of the plurality of semiconductor patterns is included in each layer of the plurality of layers, and
the plurality of semiconductor patterns face the same word line.

7. The semiconductor device of claim 1, wherein
each layer of the plurality of layers includes a plurality of semiconductor patterns that are positioned along the first direction, and
the plurality of semiconductor patterns are connected to the same bit line.

8. The semiconductor device of claim 7, wherein
the bit line connection portion is disposed in a first region that overlaps a second region in the second direction on a plane, and the plurality of semiconductor patterns are positioned at the second region.

9. The semiconductor device of claim 1, wherein
the plurality of layers include a first layer and a second layer, the first layer and the second layer sequentially stacked on the substrate, and
the bit line connection portion in the first layer and the bit line connection portion in the second layer are separate in a plane view.

10. The semiconductor device of claim 9, wherein
the bit line connection portion in the first layer and the bit line connection portion in the second layer are positioned along the first direction on a plane.

11. The semiconductor device of claim 1, wherein the capacitor in each layer of the plurality of layers includes:
a first capacitor electrode that contacts the semiconductor pattern, the first capacitor electrode in a form of pillar surrounded by a side wall;
a second capacitor electrode that passes through the first capacitor electrode in the third direction; and
a dielectric layer that is positioned between the first capacitor electrode and the second capacitor electrode.

12. The semiconductor device of claim 11, wherein
the plurality of layers includes a first layer and a second layer, the first layer and the second layer sequentially stacked on the substrate, and
the capacitor in the first layer and the capacitor in the second layer are positioned along the third direction and share the same second capacitor electrode.

13. The semiconductor device of claim 1, wherein
a cross-sectional area of the word line protrusion increases when approaching the semiconductor pattern along the third direction.

14. A semiconductor device comprising:
a stack structure including a plurality of layers stacked on a substrate,
wherein each layer of the plurality of layers includes:
a bit line structure that includes a bit line and a bit line protrusion, the bit line extending in a first direction parallel with the substrate, the bit line protrusion protruding from the bit line in a second direction intersecting with the first direction;
a bit line connection portion that extends through the bit line protrusion in a third direction;
a semiconductor pattern that is electrically connected to the bit line, the semiconductor pattern extending in the second direction;
a word line structure that includes a word line and a word line protrusion, the word line extending in the third direction perpendicular to the substrate, the word line protrusion protruding in the first direction from the word line; and
a capacitor that is electrically connected to the semiconductor pattern, and
wherein the word line faces a first surface of the semiconductor pattern, the word line protrusion faces a second surface of the semiconductor pattern, and the second surface extends vertically from the first surface.

15. The semiconductor device of claim 14, wherein
the bit line connection portion extends in a direction approaching the substrate and is connected to a lower wiring layer, the lower wiring layer positioned between the substrate and the stack structure.

16. The semiconductor device of claim 15, wherein
the word line extends in a direction away from the substrate and is connected to an upper wiring layer, the upper wiring layer positioned on top of the stack structure.

17. The semiconductor device of claim 14, wherein
a first side of the bit line is connected to a plurality of semiconductor patterns, and a second side of the bit line is connected to the corresponding bit line protrusion, the plurality of semiconductor patterns positioned along the first direction.

18. The semiconductor device of claim 14, wherein
the word line passes through the plurality of layers in the third direction, and
a plurality of semiconductor patterns are included in the plurality of layers, respectively, and a plurality of second surfaces of the plurality of semiconductor patterns are positioned along the third direction facing a plurality of word line protrusions connected to the word line, respectively.

19. The semiconductor device of claim 14, wherein
a cross-sectional area of the word line protrusion increases when approaching the semiconductor pattern along the third direction.

20. A semiconductor device comprising:
a bit line structure that includes a bit line and a bit line protrusion, the bit line extending in a first direction parallel with a substrate, the bit line protrusion protruding from the bit line in a second direction intersecting with the first direction;
a bit line connection portion that extends from the bit line protrusion in a third direction perpendicular to the substrate;
a semiconductor pattern that is connected to the bit line, the semiconductor pattern extending in the second direction;
a capacitor that is connected to the semiconductor pattern; and
a word line structure that includes a word line and a word line protrusion, the word line facing a side surface of the semiconductor pattern and extending in the third direction, the word line protrusion protruding in the first direction from the word line and facing an upper surface of the semiconductor pattern.
